(19) United States
(12) Patent Application Publication
(10) Pub. No.: US 2026/0239644 A1
(43) Pub. Date: Aug. 13, 2026

(54) METHODS OF TUNING GATE DIELECTRICS AND THE STRUCTURES THEREOF

(71) Applicant: Taiwan Semiconductor Manufacturing Co., Ltd., Hsinchu (TW)

(72) Inventors: Hsueh-Ju Chen, Taipei City (TW); Tsung-Da Lin, Hsinchu (TW); Chi On Chui, Hsinchu (TW)

(21) Appl. No.: 19/214,677

(22) Filed: May 21, 2025

Related U.S. Application Data
(60) Provisional application No. 63/757,477, filed on Feb. 12, 2025.

(51) Int. Cl. H10D 30/01

(52) U.S. Cl. CPC H10D 30/0193

(57) ABSTRACT

A method includes forming a plurality of semiconductor nanostructures, and forming a hard mask comprising a top portion over the plurality of semiconductor nanostructures, inner portions between the plurality of semiconductor nanostructures, and sidewall portions on sidewalls of the plurality of semiconductor nanostructures. The method further includes etching the sidewall portions of the hard mask, with at least a top portion of the hard mask remaining, performing a first oxidation process to oxidize sidewall portions of the semiconductor nanostructures to form first oxide layers, removing the top portion and the inner portions of the hard mask, and performing a second oxidation process to oxidize top portions and the bottom portions of the semiconductor nanostructures to form second oxide layers. The second oxide layers comprise the first oxide layers. The second oxide layers encircle remaining portions of the plurality of semiconductor nanostructures.

### PRIORITY CLAIM AND CROSS-REFERENCE

This application claims the benefit of the following provisionally filed U.S. Patent application: Application No. 63/757,477, filed on Feb. 12, 2025, and entitled “SEMICONDUCTOR STRUCTURE AND METHOD FOR FORMING THE SAME,” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12-18, 19A, 19B, 20A, 20B, 21A, and 21B illustrate the views of intermediate stages in the formation of nanostructure transistors in accordance with some embodiments.

FIGS. 22-27 illustrate cross-sectional views of intermediate stages in the formation of interfacial layers in accordance with some embodiments.

FIGS. 28 and 29 illustrate the cross-sectional views of intermediate stages in the formation of interfacial layers for transistors with different channel lengths in accordance with some embodiments.

FIGS. 30A, 30B, and 31 illustrate the views of intermediate stages in the formation of interfacial layers for transistors with different channel spacings in accordance with some embodiments.

FIG. 32 illustrates a process flow for forming a nanostructure transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor and the formation methods are provided. In accordance with some embodiments, the channel regions (nanostructures) of transistors are oxidized in two oxidation processes. In the first oxidation process, the sidewalls of the nanostructures are oxidized. In the second oxidation process, top surface portions and bottom surface portions and the sidewall portions of the nanostructures are oxidized. The nanostructures are thus thicker at sidewalls and at corner regions than the top surface portions and bottom surface portions. The gate-to-channel leakage is thus reduced, and the reliability is improved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

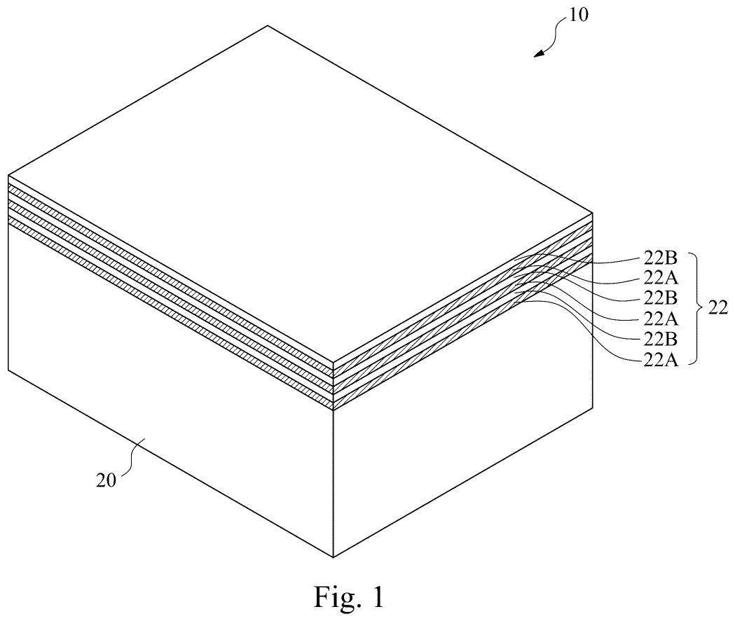

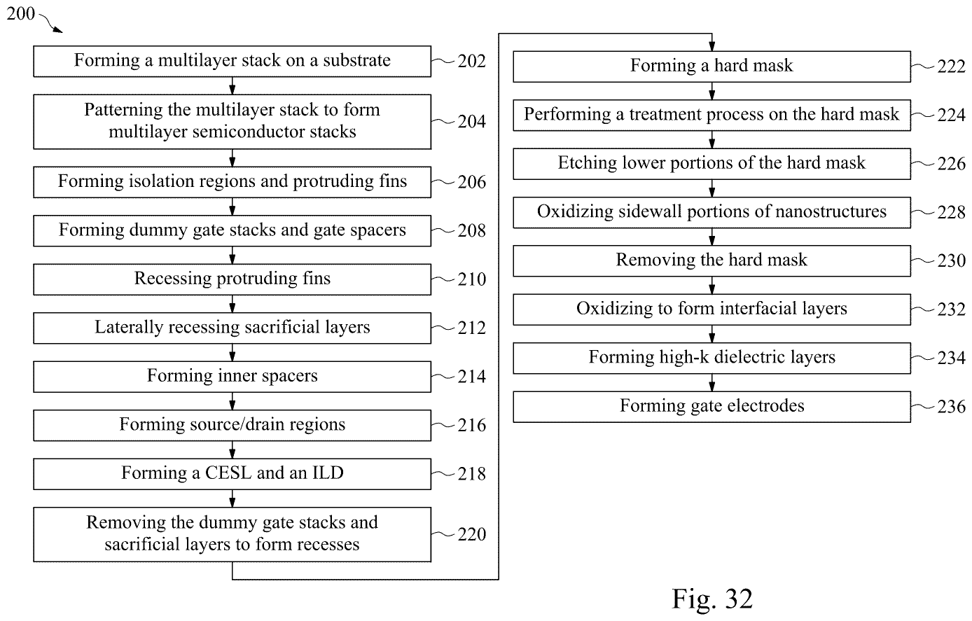

FIGS. 1-4, 5A, 5B, 6A, 6B, 7A, 7B, 8A, 8B, 9A, 9B, 10A, 10B, 11A, 11B, 12-18, 19A, 19B, 20A, 20B, 21A, and 21B illustrate the cross-sectional views of intermediate stages in the formation of a GAA transistor in accordance with some embodiments of the present disclosure. The corresponding processes are also reflected schematically in the process flow shown in FIG. 32.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 as shown in FIG. 32. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

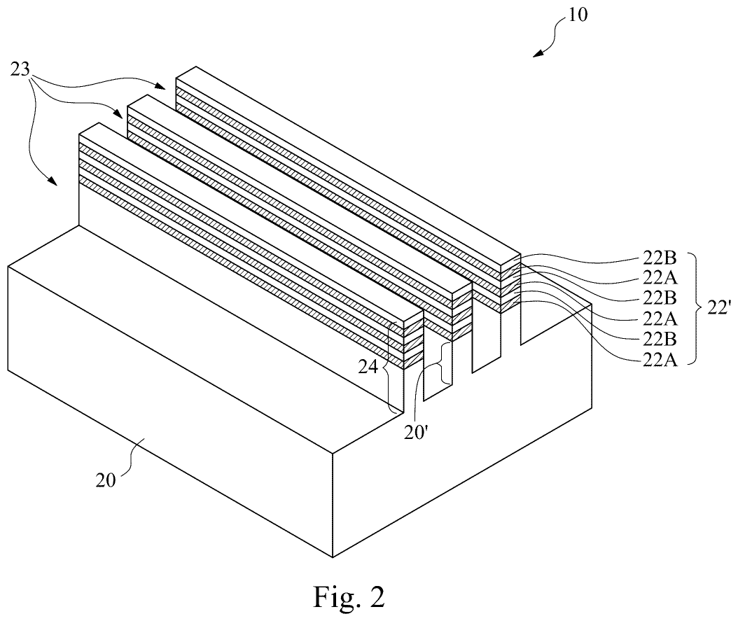

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 32. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

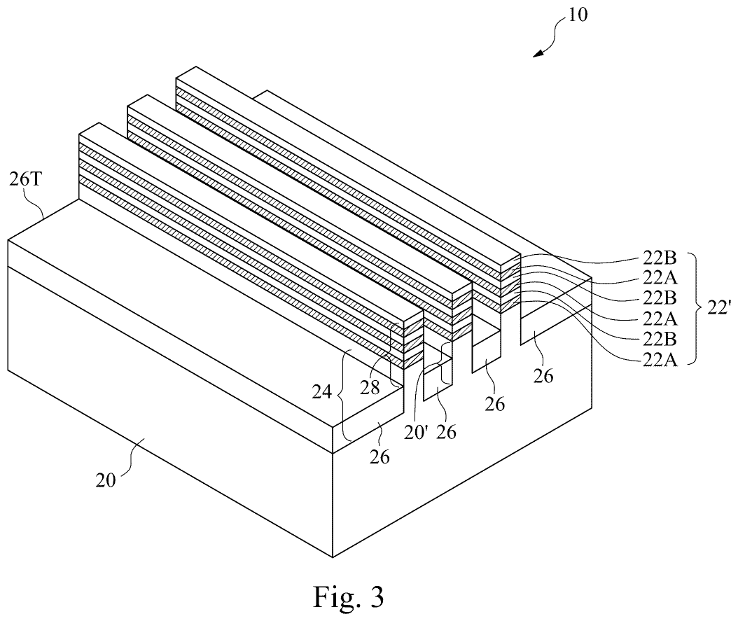

FIG. 3 illustrates the formation of isolation regions 26, which are also referred to as Shallow Trench Isolation (STI) regions throughout the description. The respective process is illustrated as process 206 in the process flow 200 as shown in FIG. 32. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

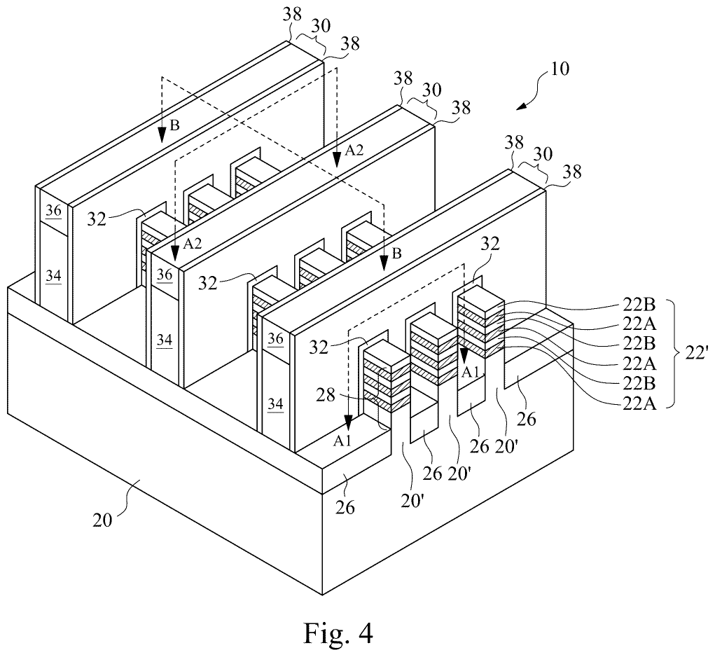

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 32. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

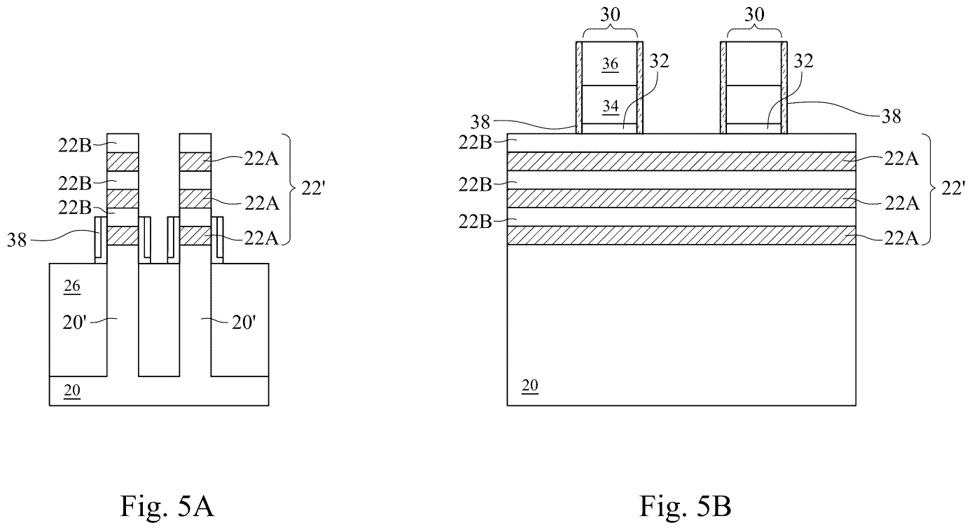

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

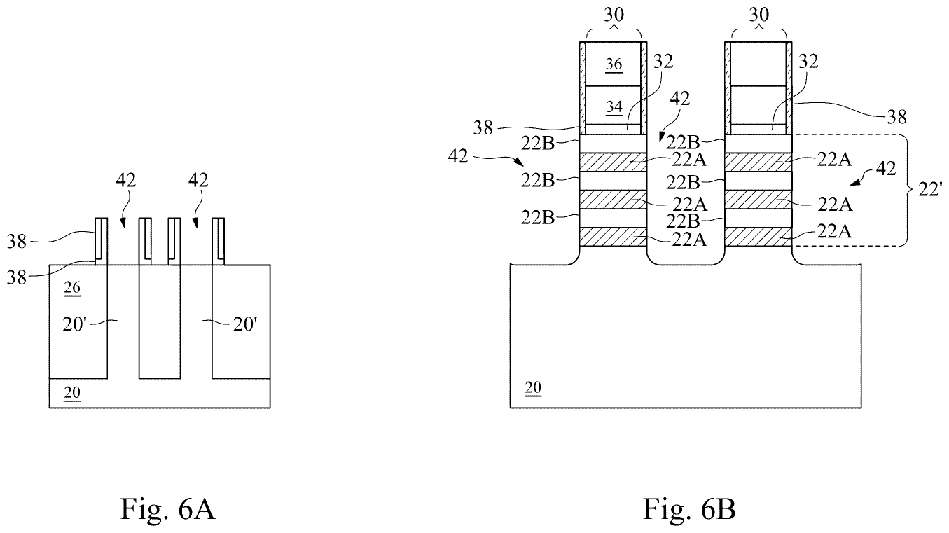

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 as shown in FIG. 32. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

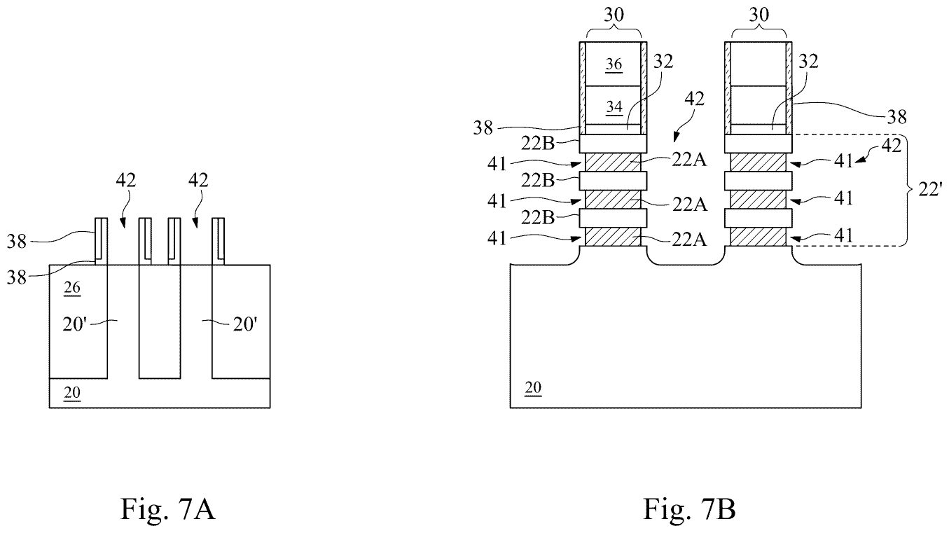

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 as shown in FIG. 32.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

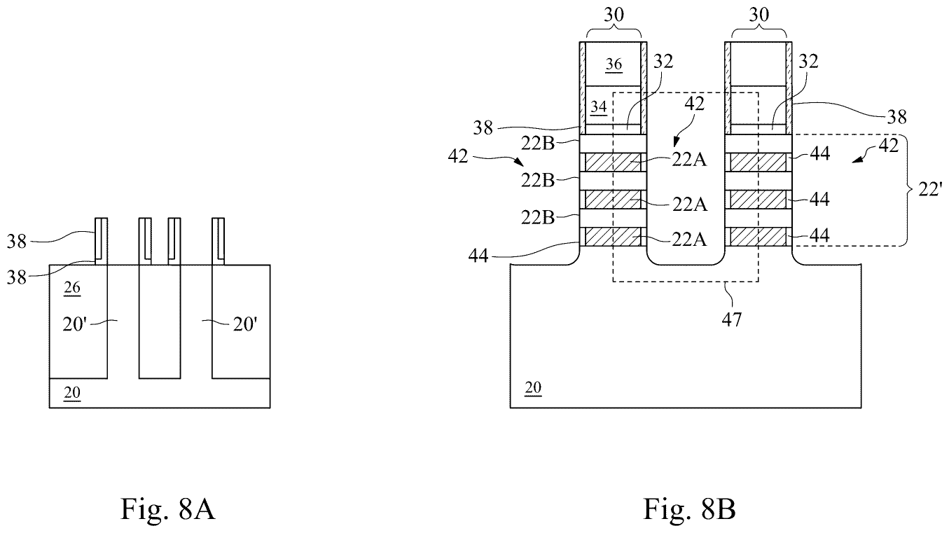

Referring to FIGS. 8A and 8B, inner spacers 44 are formed. The respective process is illustrated as process 214 in the process flow 200 as shown in FIG. 32. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers 44 may be single-layer spacers, or may include a plurality of sub layers (such as two to three sub layers).

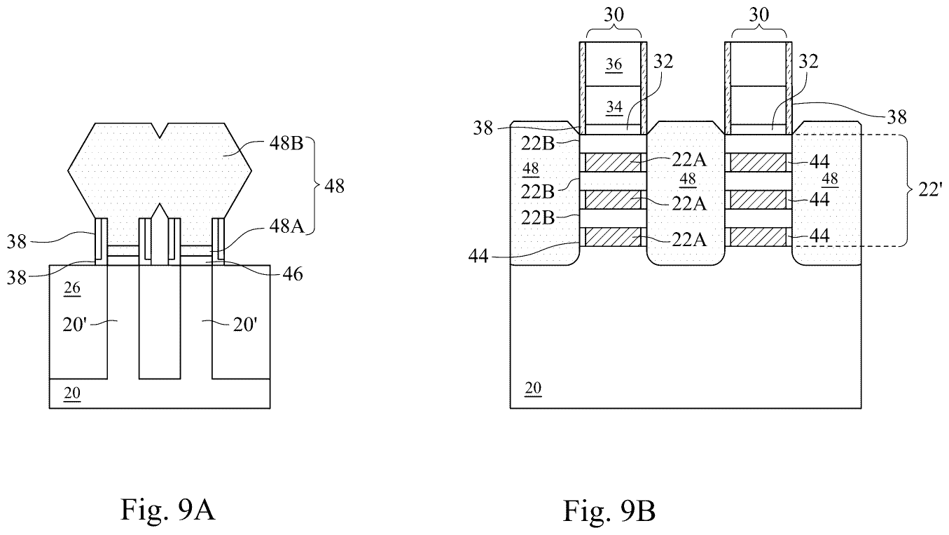

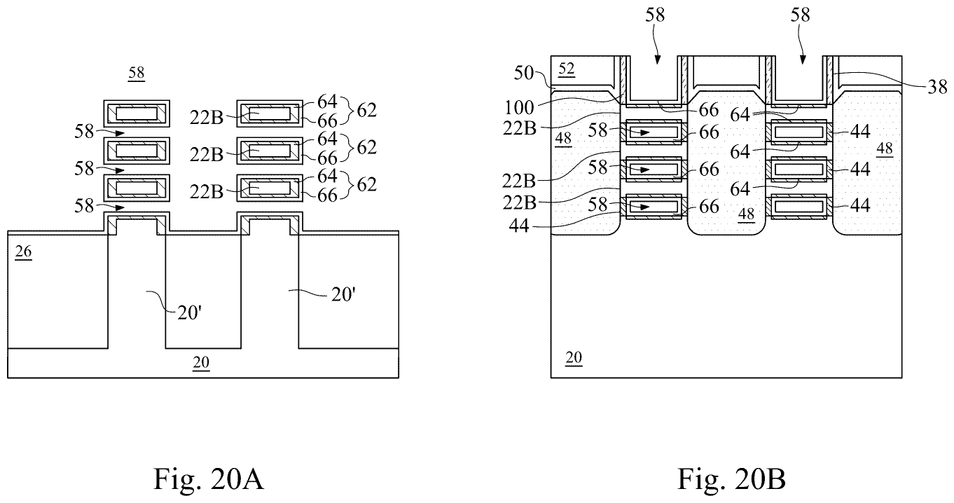

Referring to FIGS. 9A and 9B, epitaxial source/drain regions 48 are formed in recesses 42. The respective process is illustrated as process 216 in the process flow 200 shown in FIG. 20. In accordance with some embodiments, the source/drain regions 48 may exert stress on the nanostructures 22B, which are used as the channels of the corresponding GAA transistors, thereby improving performance.

Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other. Voids (air gaps) 49 may be generated.

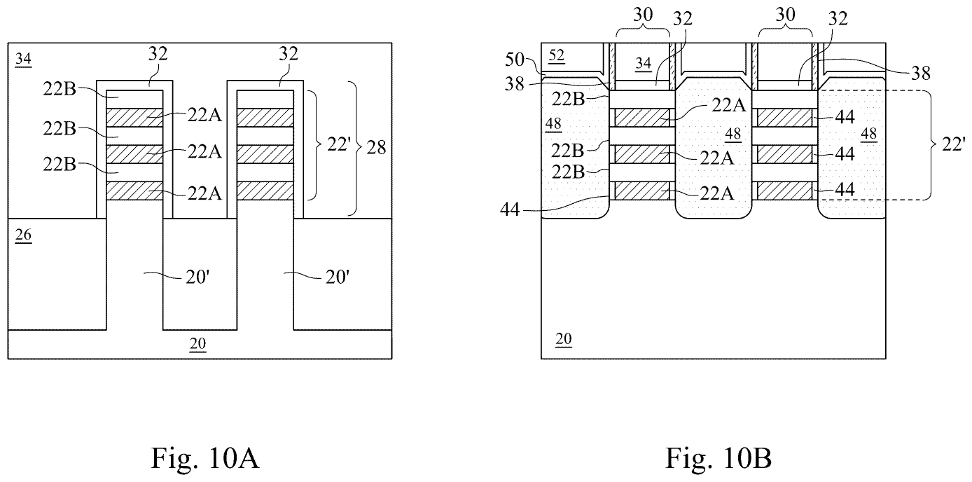

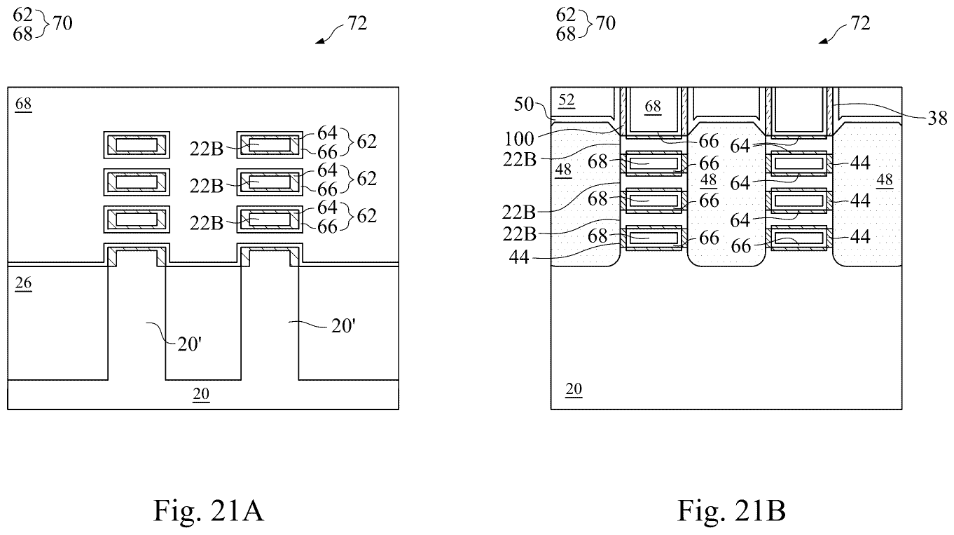

Referring to FIGS. 10A and 10B, Contact Etch Stop Layer (CESL) 50 and Inter-Layer Dielectric (ILD) 52 are formed. The respective process is illustrated as process 218 in the process flow 200 as shown in FIG. 32. The corresponding structure is also shown in FIG. 21. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

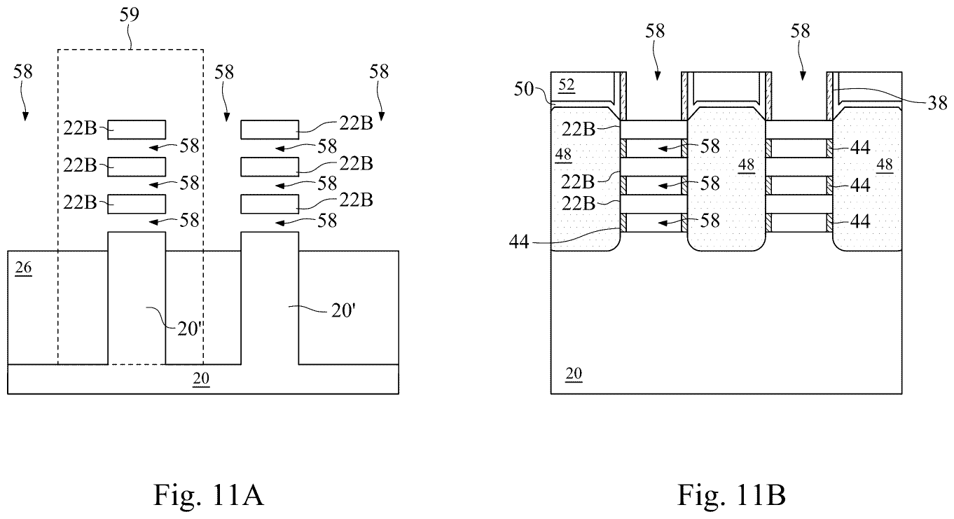

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 220 in the process flow 200 as shown in FIG. 32.

Sacrificial layers 22A are then removed to extend recesses 58 between nanostructures 22B. The respective process is also illustrated as process 220 in the process flow 200 as shown in FIG. 32. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

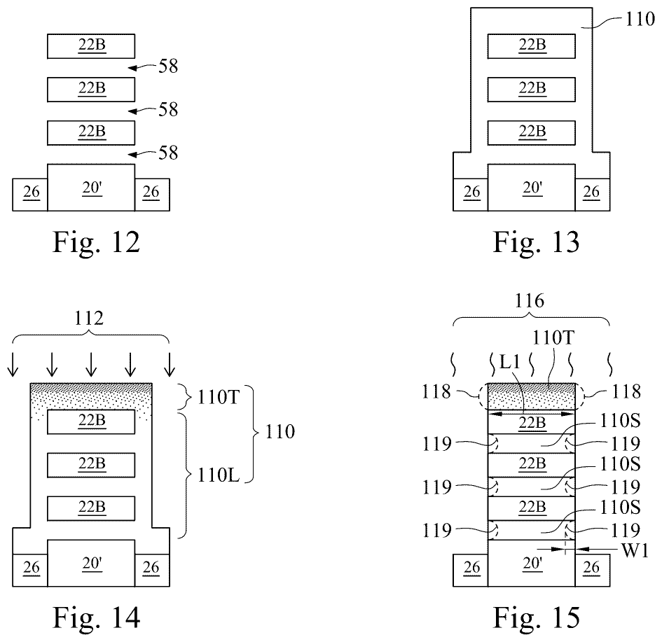

FIGS. 12 through 18 illustrate the views in the formation of interfacial layer 64 encircling nanostructures 22B in accordance with some embodiments. FIG. 12 illustrates a portion of the region 59 in FIG. 11A.

Referring to FIG. 13, hard mask 110 is formed. The respective process is illustrated as process 222 in the process flow 200 as shown in FIG. 32. Hard mask 110 may comprise a metal oxide, a metal nitride, a metal oxynitride, a metal nitricarbide, a metal oxynitricarbide, or the like. The metal in the hard mask 110 may include Al, Hf, Zr, Ti, La, or the like, or combinations thereof, while other metals may also be used. Non-metal containing materials may also be used to form hard mask 110.

In accordance with some embodiments, hard mask 110 may be deposited through a conformal deposition process, such as ALD, CVD, or the like, so that the spacings between nanostructures 22B are filled. For example, when hard mask 110 comprises a metal oxide, hard mask 110 may be deposited through ALD using a chlorine-based precursor or a metal-organic precursor, and a reactant (oxidant or a nitridation species). The wafer temperature in the deposition process may be in the range between about 100° C. and about 500° C. The pressure of the deposition chamber may be in the range between about 0.1 Torr and about 10 Torr.

Referring to FIG. 14, treatment process 112 is performed on hard mask 110. The respective process is illustrated as process 224 in the process flow 200 as shown in FIG. 32. Treatment process 112 may be an anisotropic treatment process, so that a top portion 110T of the hard mask 110 is treated, and its property altered, while a lower portion 110L of hard mask 110 is not treated. The lower portion 110L includes sidewall portions on sidewalls of nanostructures 22B, and inner portions between nanostructures 22B. The treatment process 112 may be performed using an oxygen-containing process gas such as O₂ or a nitrogen-containing process gas such as NH₃, or the combination thereof. Other process gases (such as a carbon-containing gas (for example, CO₂)) that may alter the property of hard mask 110 may also be used.

The treatment process may either alter the composition of hard mask 110 by adding an element(s) not in the deposited hard mask 110, increasing the atomic percentage of an element of the deposited hard mask 110, and/or improving the quality (such as the density) of hard mask 110.

For example, when hard mask 110 comprises a metal oxide such as aluminum oxide, NH₃ may be used to add nitrogen and alter the top portion 110T as aluminum oxynitride, and thus causing a higher etching selectivity between lower portion 110L and top portion 110T. When hard mask 110 comprises a metal oxide such as aluminum oxide, oxygen (O₂) may also be used to improve the quality of hard mask 110, for example, by fixing defects and density of the top portion 110T through adding oxygen. The lower portion 110L, on the other hand, is not treated. Accordingly, the top portion 110T and lower portion 110L may comprise a same material, but have different properties such as different density, different porosity, and/or different dangling bonds.

In accordance with some embodiments, the treatment gas may comprise the gas for adding the intended element (as discussed above) or densify hard mask 110, and is free from inert gases such as N₂, He, Ar, Xe, and/or the like. Alternatively, besides the gas for adding the intended element or densifying hard mask 110, inert gases such as N₂, He, Ar, Xe, and/or the like may be added. The wafer temperature during the treatment process 112 may be in the range between about 100° C. and about 600° C. The pressure in the treatment chamber may be in the range between about 0.01 Torr and about 10 Torr.

Next, as shown in FIG. 15, etching process 116 is performed to etch the lower portion 110L of hard mask 110. The respective process is illustrated as process 226 in the process flow 200 as shown in FIG. 32. In accordance with some embodiments, etching process 116 comprises an isotropic etching process. The etching chemical is selected to etch lower portion 110L, with the top portion 110T that has been treated at least having reduced etching rate ET-110T than the etching rate ER-110L of the lower portion 100L. For example, the etching rate ratio ER-110T/ER-110L may be smaller than about 0.1, and may be in the range between about 0.01 and about 0.1.

The etching process 116 may be performed through dry (gas-phase) etching or wet etching. For example, when wet etching is used, a chemical solution of NH₄OH, HCl, and/or an oxidant may be used. The oxidant may be, or may not be, mixed in De-ionized (DI) water. The oxidant may include, for example, hydrogen peroxide.

In accordance with some embodiments, after the etching process 116, the lower portion 110L is removed, and the sidewalls of nanostructures 22B are exposed. The top portion 110T may remain. It is appreciated that top portion 110T may (or may not) have overhang portions laterally protruding beyond the edges of nanostructures 22B, wherein dashed lines 118 schematically illustrates the sidewalls of the overhang portions. The remaining portions of hard mask 110 may have portions 110S in the spacing between nanostructures 22B.

The outer sidewalls of portions 110S may be vertically aligned with the outer edges of nanostructures 22B, or may be laterally recessed. For example, dashed lines 119 represent the outer sidewalls when portions 110S are laterally recessed. The lateral recessing may help the formation of thicker IL at the corners of nanostructures 22B. In accordance with some embodiments, the ratio L1/W1 may be greater than about 0.05, and may be in the range between about 0.05 and about 0.1, wherein W1 is the width of the recessing, and LD1 is the length of nanostructures 22B.

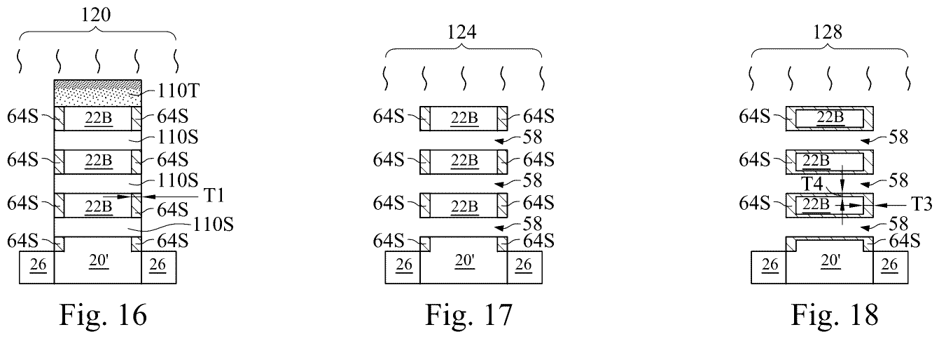

In accordance with alternative embodiments, after the etching process 116, the sidewall portions (included in lower portions 110L) of hard mask 110 are thinned, and the resulting thinned sidewall portions may have thicknesses (measured in lateral direction) small enough to allow nanostructures 22B to be oxidized in the process shown in FIG. 16. In accordance with some embodiments, the thinned sidewall portions have thicknesses smaller than about 10 percent of the thickness (measured in vertical direction) of the top portions 110T, and less than about 10 percent of the thickness of the sidewall portions before the etching process 116 is performed.

In accordance with some embodiments, after the etching process 116, one cycle or more cycles may be performed. Each cycle includes the processes shown in FIGS. 13-15. In each of the cycles, a hard mask is formed on the remaining top portion 110T, portions 110S, and nanostructures 22B. The material of the hard mask deposited in each cycle may be the same as or different from the material of hard masks in other cycles. Forming hard masks in different cycles using different materials may improve the etching resistance.

As may be realized from FIGS. 13, 14, and 15, each of the cycles results in the thickness (measured in vertical direction, the height) of the top portion of the hard mask 110 to be increased, until the height is great enough to protect the top nanostructure 22B from being oxidized from top in subsequent oxidation process 120. In accordance with alternative embodiments, no more cycle is performed.

In accordance with some embodiments, after the etching process 116, the process proceeds to the oxidation process 120 as shown in FIG. 16. The respective process is illustrated as process 228 in the process flow 200 as shown in FIG. 32.

In accordance with some embodiments, the oxidation gas for the oxidation process 120 may comprise O₂, and may or may not include inert gases such as N₂, He, Ar, Xe, and/or the like. The oxidation process may be performed by generating a plasma from the oxidation gas, and using the plasma for the oxidation process 120. The plasma used for the oxidation process 120 may comprise ions and radicals of the oxidation gas. Alternatively, the ions may be removed, leaving radicals for the oxidation process 120. The wafer temperature during the oxidation process 120 may be in the range between about 100° C. and about 600° C. The pressure of the oxidation chamber may be in the range between about 0.01 Torr and about 10 Torr.

As a result of the oxidation process 120, oxide layers 64S are formed on the sidewalls of nanostructures 22B. The thickness T1 of oxide layers 64S may be in the range between about 1 Å and about 10 Å. Due to the protection of top portion 110T and inner portions 100S, no oxide is generated on the top surfaces and bottom surfaces of at least inner portions of nanostructures 22B.

After the formation of oxide layers 64S, the remaining top portion 110T and inner portions 100S of hard mask 110 are removed through etching process 124 (FIG. 17), which comprises an isotropic etching process. The respective process is illustrated as process 230 in the process flow 200 as shown in FIG. 32. The etching process 124 may be performed through dry (gas-phase) etching or wet etching. The etching chemical may be selected from the same candidate group of, and may be the same as or different from, the etching chemical used for etching process 116 (FIG. 15).

Depending on the material of the top portion 110T, when wet etching is used, a chemical solution of NH₄OH, HCl, and/or an oxidant may be used. The oxidant may be, or may not be, mixed in De-ionized (DI) water. The oxidant may include, for example, hydrogen peroxide. When the chemical is the same as the chemical used in etching process 116, etching process 124 may adopt longer etching time, higher etching chemical temperature, and/or the like than etching process 116 to ensure top portion 110T and inner portions 100S are removed. After the etching process 124, recesses (spacings) 58 are re-generated.

Referring to FIG. 18, oxidation process 128 is performed to form oxide layers 64 (also referred to as interfacial layers (ILs) 64). The respective process is illustrated as process 232 in the process flow 200 as shown in FIG. 32. The oxidation process 128 may be performed using oxygen, for example, by generating plasma from the oxygen-containing gas. The oxidation process 128 may also comprise a chemical oxidation process. As a result, at the top surfaces and bottom surfaces of nanostructures 22B, ILs 64 are formed and have thickness T4, which is measured in a vertical direction and at the center of nanostructures 22B.

The sidewall portions of ILs 64 formed on the sidewalls of nano structures 22B include the previously formed oxide layer 64S (FIG. 17) and the newly formed oxide, and thus have thickness T3, which is measured in a horizontal direction and at the middle levels of nanostructures 22B. Thickness T3 is greater than thickness T4. The difference (T3−T4) may be in the range between about 1 Å and about 10 Å. Ratio T3/T4 may be greater than about 1.1, and may be in the range between about 1.1 and about 4, for example.

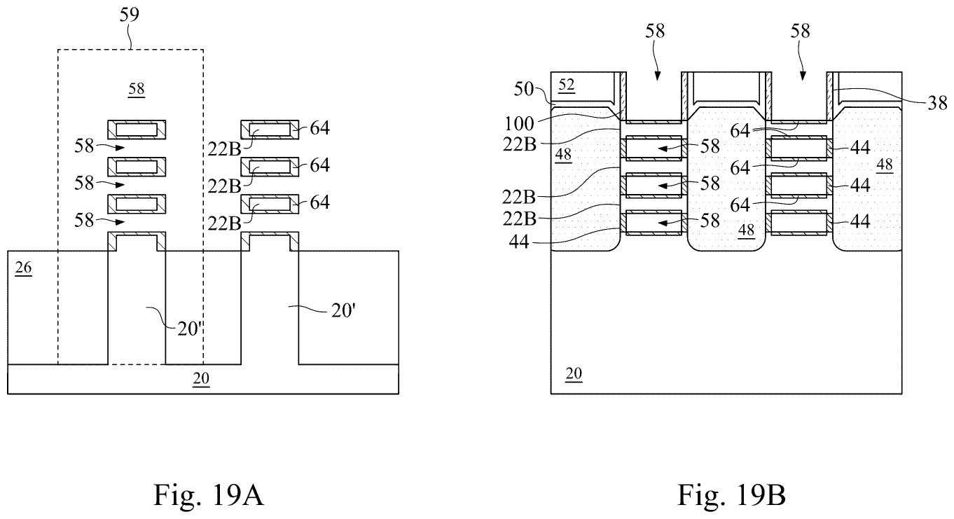

FIG. 19A illustrates a structure formed by the preceding processes, wherein a large region of the structure is illustrated. FIGS. 19A and 19B illustrate the cross-sectional view obtained from the same cross-sections shown in FIGS. 11A and 11B, respectively. As shown in FIG. 19B, ILs 64 are formed on the exposed surfaces that are exposed to spacings 58.

Referring to FIGS. 20A and 20B, high-k dielectric layers 66 are deposited over ILs 64. The respective process is illustrated as process 234 in the process flow 200 as shown in FIG. 32. ILs 64 and high-k dielectric layers 66 are individually and collectively referred to as gate dielectrics 62. In accordance with some embodiments, high-k dielectric layers 66 comprise one or more high-k dielectric layers. For example, high-k dielectric layers 66 may include a metal oxide or a silicate of hafnium, aluminum, zirconium, lanthanum, manganese, barium, titanium, lead, multi-layers thereof, and/or combinations thereof.

Gate electrodes 68 are then formed, as shown in FIGS. 21A and 21B. The respective process is illustrated as process 236 in the process flow 200 as shown in FIG. 32. Gate dielectrics 62 and gate electrodes 68 collectively form replacement gate stacks 70. In the formation process of gate electrodes 68, conductive layers are first formed over the high-k dielectric layers 66, so that the remaining portions of recesses 58 are filled, followed by a planarization process such as a CMP process or a mechanical grinding process to remove excess materials. Gate electrodes 68 may include a metal-containing material such as TiN, TaN, TiAl, TiAlC, cobalt, ruthenium, aluminum, tungsten, combinations thereof, and/or multilayers thereof. GAA transistor 72 is thus formed.

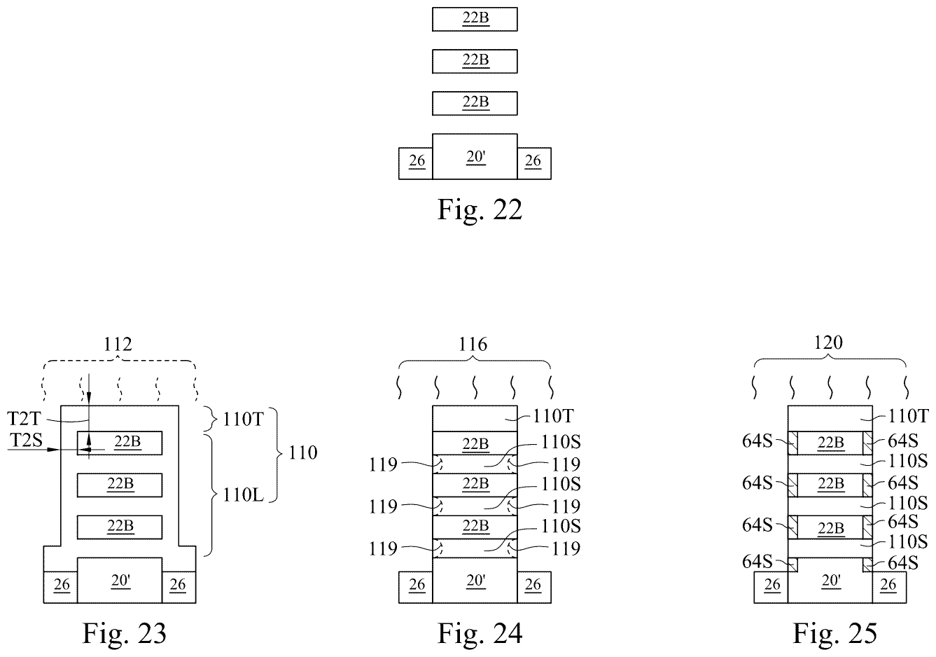

FIGS. 22-27 illustrate the formation of ILs 64 in accordance with alternative embodiments. These embodiments are similar to the preceding embodiments, except that the top portion 110T are formed thicker (as deposited) than sidewall portions. Accordingly, after the removal of the sidewalls (lower portions 110L), the top portions 100T still have some parts remaining. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 1-11A/11B, and FIG. 22 illustrates a resulting structure, which is essentially the same as the structure shown in FIG. 12. Next, referring to FIG. 23, hard mask 110 is deposited.

In accordance with some embodiments, hard mask 110 is deposited as having thickness T2T of the top portion being greater than the thickness T2S of the lower portions 110L. The spacings between nanostructures 22B are also fully filled. The difference (T2T−T2S) may be greater than about 1 Å, and may be in the range between about 1 Å and about 5 Å, and may also be greater than about 5 Å.

In accordance with some embodiments, the material of hard mask 110 may be selected from the same group of candidate materials as discussed in the preceding embodiments. For example, hard mask 110 may comprise a metal oxide, a metal nitride, a metal oxynitride, a metal nitricarbide, a metal oxynitricarbide, or the like. The metal in the hard mask 110 may include Al, Hf, Zr, Ti, La, or the like, or combinations thereof, while other metals may also be used. Non-metal containing materials may also be used to form hard mask 110.

In an embodiment in which hard mask 110 comprises a metal oxide, hard mask 110 may be deposited through ALD using a chlorine-based precursor or a metal-organic precursor, and a reactant (oxidant or nitridation species). The wafer temperature in the deposition may be in the range between about 100° C. and about 500° C. The pressure of the deposition chamber may be in the range between about 0.1 Torr and about 10 Torr.

In accordance with some embodiments, to achieve a large difference between thicknesses T2T and T2S, the deposition process comprises the effect of both of isotropic deposition and anisotropic deposition. In accordance with some embodiments, the deposition is achieved through ALD, which method itself is isotropic. The anisotropic effect is achieved by utilizing the smaller diffusion lengths of precursor and reactant at sheet-top compared the diffusion lengths at sheet-sidewalls. For example, the pulsing time for conducting the metal-containing precursor may be shortened, and the pulsing time may be shorter than the pulsing time in the embodiments discussed referring to FIG. 13. The purging time of the metal-containing precursor and the pulsing time and the purging time of the reactant, on the other hand, has little effect to the diffusion lengths, and thus may be the same as in the embodiment discussed referring to FIG. 13.

With the smaller diffusion length, there is smaller amount of the molecules of the metal-containing precursor adsorbed on the sidewalls of nanostructures 22B and in the spacings between nanostructures 22B in each pulsing process. Accordingly, in each ALD cycle, the hard mask 110 is grown faster at the top of nanostructures 22B than in the spacings and on the sidewalls of nanostructures 22B.

In accordance with some embodiments, no treatment process is performed on hard mask 100 to alter the properties of the top portion 100T. In accordance with alternative embodiments, a treatment process 112 is performed to alter the properties of the top portion 100T to be different from that of lower portions 100L. The details of the treatment process 112 may be found referring to FIG. 14, and are not repeated herein. The treatment process 112 is shown as being dashed to indicate that it may or may not be performed.

FIG. 24 illustrates the etching process 116 of the lower portions 110L, leaving inner portions 110S between nanostructures 22B. The details may be found referring to the discussion of FIG. 15, and are not repeated herein. In the etching process 116, since the top portions 110T are thicker than the lower portions 110L, the sidewall portions of hard mask 110 on the sidewalls of nanostructures 22B are removed, while the top portions have parts left. If the top portion 110T is further treated, the remaining top portions 110T may be thicker.

In accordance with some embodiments, after the etching process 116, one cycle or more cycles may be performed. Each cycle includes the processes shown in FIGS. 23-24. In each of the cycles, a hard mask is formed on the remaining top portion 110T, portions 110S, and nanostructures 22B. The material of the hard mask deposited in each cycle may be the same as or different from the material of hard masks in other cycles. Forming hard masks in different cycles using different materials may improve the etching resistance.

Each of the cycles results in the thickness (measured in vertical direction, the height) of the top portion of the hard mask 110 to be increased, until the height is great enough to protect the top nanostructure 22B from being oxidized from top in subsequent oxidation process 120. In accordance with alternative embodiments, no more cycle is performed.

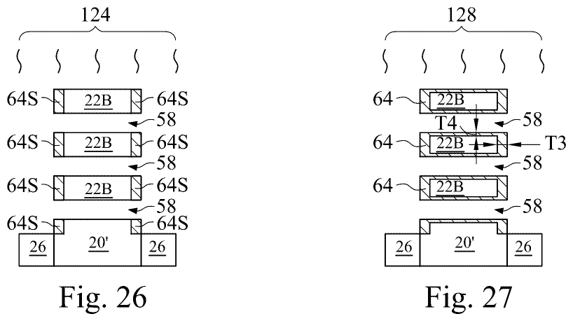

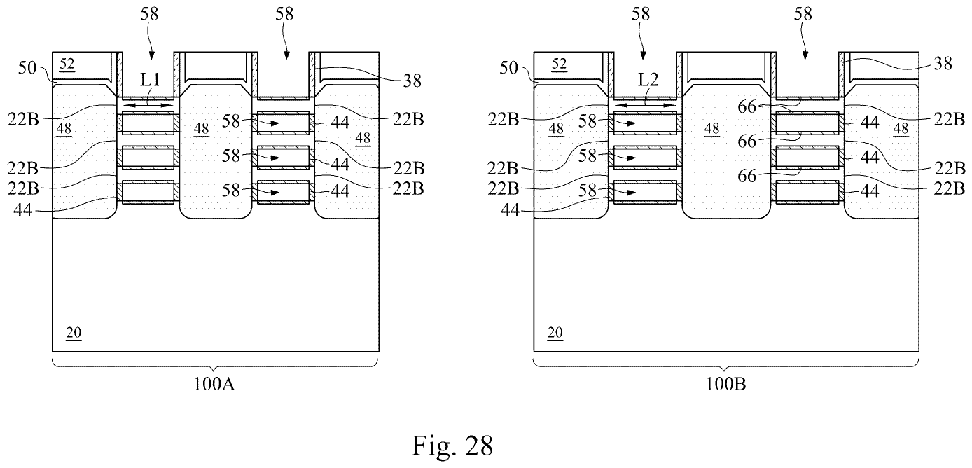

FIG. 25 illustrates the oxidation process 120 to form oxide layers 64S. FIG. 26 illustrates the etching process 124 for removing the remaining portions of hard mask 110. FIG. 28 illustrates the oxidation process 126 to form the ILs 64. The details of these processes may be found referring to the discussion of FIGS. 16, 17, and 18, and are not repeated herein.

The resulting structure of FIG. 27 is also shown in FIGS. 19A and 19B. Next, the processes as shown in FIGS. 20A, 20B, 21A, and 21B are performed to finish the formation of GAA transistor 72.

FIGS. 28 through 31 illustrate the processes of forming transistors that have different structures in different device regions. The device regions 100A, 100B, 100C, and 100D may be in the same device die, and may be formed sharing common processes such as the processes shown in preceding figures.

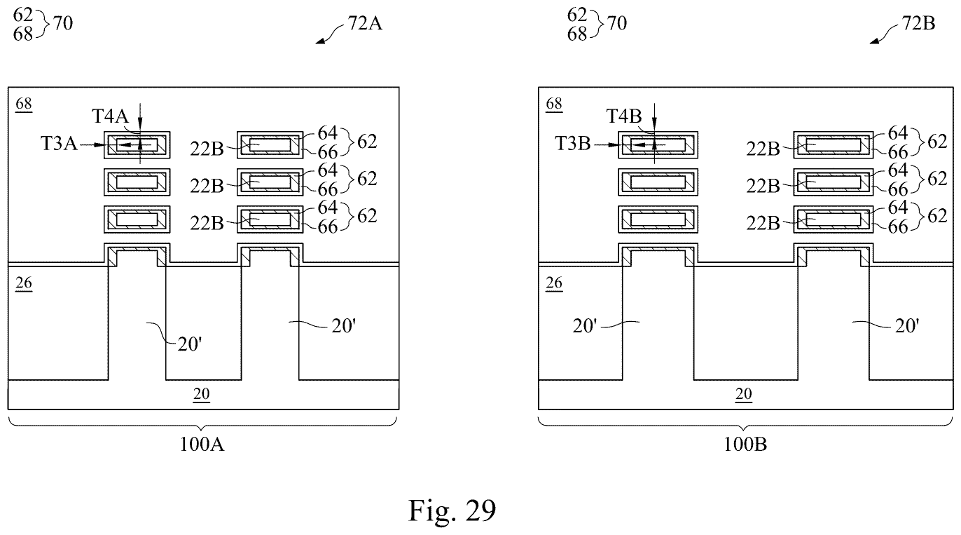

FIGS. 28 and 29 illustrate device regions 100A and 100B, in which GAA transistors 72A and 72B are formed as having different channel lengths. The structures shown in FIG. 28 correspond to the structure and the process shown in FIG. 19B. The channel length L2 in device region 100B is greater than the channel length L1 in device region 100A. In accordance with some embodiments, channel length ratio L2/L1 may be greater than about 1.2, and may be in the range between about 1.2 and about 5.

FIG. 29 illustrates the resulting GAA transistors 72A and 72B, and the illustrated structures correspond to the structure shown in FIG. 21A. In accordance with some embodiments, the thickness difference (T3A−T4A) in device region 100A and the thickness difference (T3B−T4B) in device region 100A may be in the range between about 1 Å and about 10 Å.

Due to the pattern loading effect, ratio T3B/T4B may be different from, and may be greater than thickness ratio T3A/T4A. Ratio (T3B/T4B)/(T3A/T4A) may be greater than about 1.1, and may be in the range between about 1.1 and about 2, for example, depending on the value of channel length ratio L2/L1.

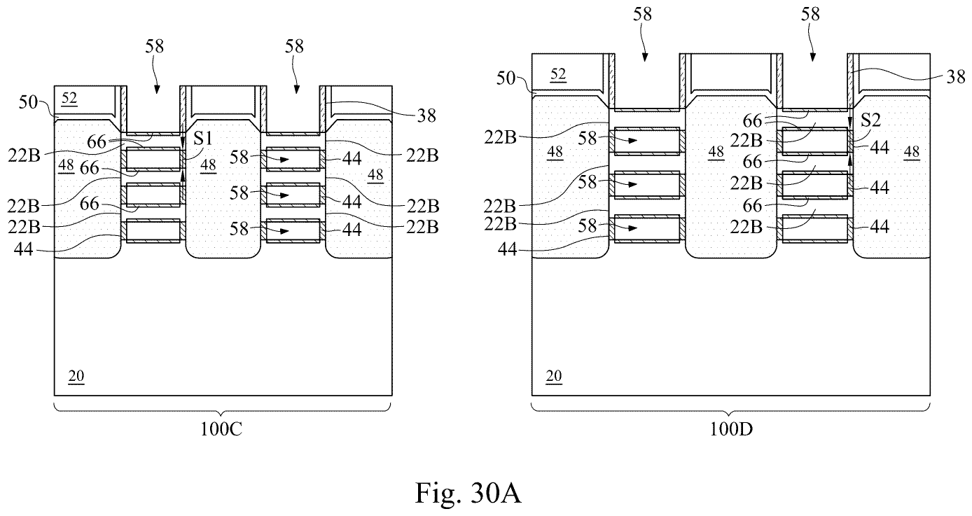

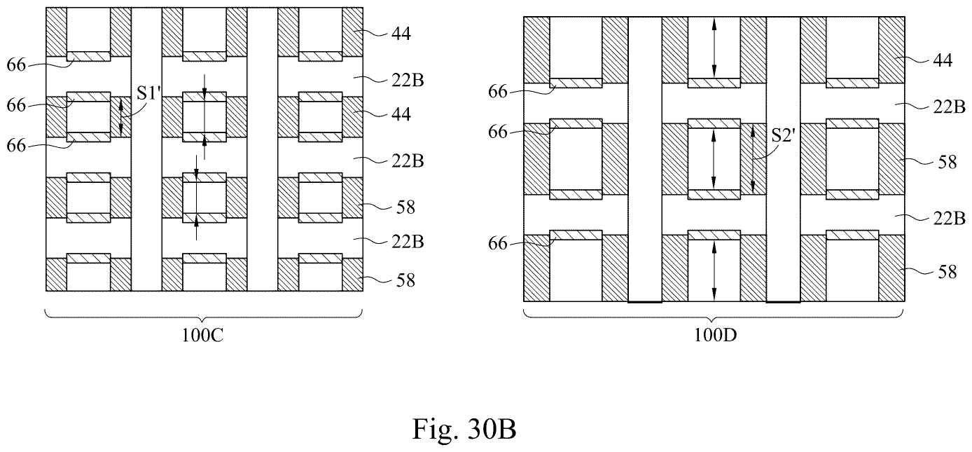

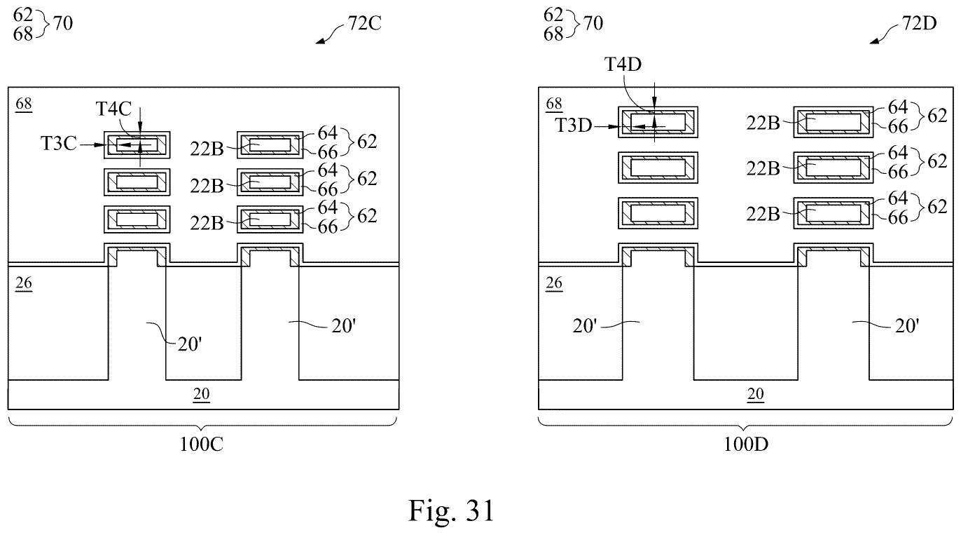

FIGS. 30A, 30B and 31 illustrate device regions 100C and 100D, in which GAA transistors 72C and 72D are formed as having different channel spacings. The structures shown in FIGS. 30A and 30B correspond to the structure and the process shown in FIG. 19B. FIG. 30A illustrate a cross-sectional view, and FIG. 30B illustrates a top view. As shown in FIG. 30A, the vertical channel spacing S2 in device region 100D is greater than the vertical channel spacing S1 in device region 100C. As shown in FIG. 30B, the horizontal channel spacing S2′ in device region 100D is greater than the horizontal channel spacing S1′ in device region 100C. In accordance with some embodiments, channel spacing ratios S2/S1 and S2′/S1′ may be greater than about 1.2, and may be in the range between about 1.2 and about 5.

FIG. 31 illustrates the resulting GAA transistors 72C and 72D, and the illustrated structures correspond to the structure shown in FIG. 21A. In accordance with some embodiments, the thickness difference (T3C−T4C) in device region 100C and the thickness difference (T3D−T4D) in device region 100C may be in the range between about 1 Å and about 10 Å.

Due to the pattern loading effect, ratio T3D/T4D may be different from, and may be greater than thickness ratio T3C/T4C. Ratio (T3D/T4D)/(T3C/T4C) may be greater than about 1.1, and may be in the range between about 1.1 and about 2, for example, depending on the value of channel spacing ratio S2/S1.

The embodiments of the present disclosure have some advantageous features. By oxidizing the sidewall portions of nanostructures before the formation of ILs that encircle the nanostructures 22B, the sidewall portions and the corners of the ILs may be formed thicker than the inner portions of the ILs in the spacings between the nanostructures. The sidewall portions and corner portions of the ILs at the sheet ends of nanostructures suffer from higher carrier concentration and higher electric fields compared to the sheet centers due to geometric effect. It is possible that there is a higher gate-to-channel leakage and increased reliability risk at the sheet ends. By increasing the thickness of the ILs at the sheet ends, the gate-to-channel leakage and reliability risk are reduced.

In accordance with some embodiments of the present disclosure, a method comprises forming a plurality of semiconductor nanostructures, wherein upper ones of the plurality of semiconductor nanostructures overlap lower ones of the plurality of semiconductor nanostructures; forming a hard mask comprising a top portion over the plurality of semiconductor nanostructures; inner portions between the plurality of semiconductor nanostructures; and sidewall portions on sidewalls of the plurality of semiconductor nanostructures; etching the sidewall portions of the hard mask, wherein at least a top portion of the hard mask remains; performing a first oxidation process to oxidize sidewall portions of the semiconductor nanostructures to form first oxide layers; removing the top portion and the inner portions of the hard mask; and performing a second oxidation process to oxidize top portions and the bottom portions of the semiconductor nanostructures to form second oxide layers, wherein the second oxide layers encircle remaining portions of the plurality of semiconductor nanostructures, and wherein the second oxide layers comprise the first oxide layers.

In an embodiment, the method further comprises, before the sidewall portions of the hard mask are etched, performing a treatment process on the top portion, wherein the sidewall portions and the inner portions are masked from the treatment process. In an embodiment, the hard mask comprises a metal compound comprising an element selected from the group consisting of oxygen, nitrogen, and a combination thereof, wherein and the treatment process is performed using a process gas comprising oxygen.

In an embodiment, the hard mask comprises a metal compound comprising an element selected from the group consisting of oxygen, nitrogen, and a combination thereof, wherein and the treatment process is performed using a process gas comprising nitrogen. In an embodiment, the treatment process comprises a plasma treatment process. In an embodiment, the top portion of the hard mask has a first thickness, and the sidewall portions of the hard mask have second thicknesses smaller than the first thickness.

In an embodiment, the method further comprises forming a plurality of sacrificial layers, wherein the plurality of semiconductor nanostructures and the plurality of sacrificial layers are located alternatingly; removing the plurality of sacrificial layers, wherein the hard mask is formed after the plurality of sacrificial layers are removed; and after the second oxide layers are formed, forming a gate stack, wherein the gate stack comprises portions between the plurality of semiconductor nanostructures.

In an embodiment, when the first oxidation process is performed, the inner portions of the hard mask comprise at least inner parts remaining. In an embodiment, after the etching the sidewall portions of the hard mask, the sidewalls of the plurality of semiconductor nanostructures are exposed. In an embodiment, after the etching the sidewall portions of the hard mask, the inner portions of hard mask are laterally recessed more than respective ones of the sidewalls of the plurality of semiconductor nanostructures.

In accordance with some embodiments of the present disclosure, a method comprises forming a plurality of semiconductor nanostructures and a plurality of sacrificial layers, wherein the plurality of semiconductor nanostructures and the plurality of sacrificial layers are located alternatingly; removing the plurality of sacrificial layers to leave spaces between the plurality of semiconductor nanostructures; oxidizing outer portions of the plurality of semiconductor nanostructures to form oxide layers that encircle inner portions of the plurality of semiconductor nanostructures, wherein each of the oxide layers comprises sidewall portions on sidewalls of the inner portions of the plurality of semiconductor nanostructures, wherein the sidewall portions have a first thickness; and top portions on tops of the inner portions of the plurality of semiconductor nanostructures, wherein the top portions have a second thickness smaller than the first thickness; and forming a gate stack in the spaces between the plurality of semiconductor nanostructures.

In an embodiment, the sidewall portions of the oxide layers are formed through more oxidation processes than the top portions. In an embodiment, the oxide layers further comprise bottom portions at bottoms of the inner portions of the plurality of semiconductor nanostructures, and wherein the bottom portions have the second thickness. In an embodiment, the oxidizing the outer portions of the plurality of semiconductor nanostructures comprises performing a first oxidation process to oxidize sidewall parts of the plurality of semiconductor nanostructures, wherein top parts and bottom parts of the plurality of semiconductor nanostructures are protected from the first oxidation process.

In an embodiment, the top parts and the bottom parts of the plurality of semiconductor nanostructures are protected by a hard mask that fills the spaces between the plurality of semiconductor nanostructures, and the method further comprises performing a second oxidation process to oxidize the top parts of the plurality of semiconductor nanostructures to form the top portions of the oxide layers.

In an embodiment, the method further comprises, before the first oxidation process, forming the hard mask on the plurality of semiconductor nanostructures; and partially etching the hard mask. In an embodiment, before the partially etching the hard mask, performing a treatment process to treat a top part of the hard mask, and a lower part of the hard mask is protected from being treated by the top portion, wherein in the partially etching the hard mask, the lower part of the hard mask is removed.

In accordance with some embodiments of the present disclosure, a method comprises forming a plurality of semiconductor nanostructures, wherein upper ones of the plurality of semiconductor nanostructures overlap lower ones of the plurality of semiconductor nanostructures; forming source and drain regions joining to opposing ends of the plurality of semiconductor nanostructures; forming an oxide layer encircling a nanostructure of the plurality of semiconductor nanostructures, wherein the oxide layer comprises a sidewall portion on a sidewall of the nanostructure, wherein the sidewall portion has a first thickness; and a top portion overlying the nanostructure; and a bottom portion overlying the nanostructure, wherein the top portion and the bottom portion have second thicknesses smaller than the first thickness; and forming a gate stack, wherein the gate stack comprises parts in spacings between the plurality of semiconductor nanostructures.

In an embodiment, a ratio of the first thickness to the second thickness is greater than about 1.2. In an embodiment, a ratio of the first thickness to the second thickness is greater than about 2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor nanostructures, wherein upper ones of the plurality of semiconductor nanostructures overlap lower ones of the plurality of semiconductor nanostructures;
forming a hard mask comprising:
a top portion over the plurality of semiconductor nanostructures;
inner portions between the plurality of semiconductor nanostructures; and
sidewall portions on sidewalls of the plurality of semiconductor nanostructures;
etching the sidewall portions of the hard mask, wherein at least a top portion of the hard mask remains;
performing a first oxidation process to oxidize sidewall portions of the semiconductor nanostructures to form first oxide layers;
removing the top portion and the inner portions of the hard mask; and
performing a second oxidation process to oxidize top portions and bottom portions of the semiconductor nanostructures to form second oxide layers, wherein the second oxide layers encircle remaining portions of the plurality of semiconductor nanostructures, and wherein the second oxide layers comprise the first oxide layers.

2. The method of claim 1 further comprising:
before the sidewall portions of the hard mask are etched, performing a treatment process on the top portion, wherein the sidewall portions and the inner portions are masked from the treatment process.

3. The method of claim 2, wherein the hard mask comprises a metal compound comprising an element selected from the group consisting of oxygen, nitrogen, and a combination thereof, wherein and the treatment process is performed using a process gas comprising oxygen.

4. The method of claim 2, wherein the hard mask comprises a metal compound comprising an element selected from the group consisting of oxygen, nitrogen, and a combination thereof, wherein and the treatment process is performed using a process gas comprising nitrogen.

5. The method of claim 2, wherein the treatment process comprises a plasma treatment process.

6. The method of claim 1, wherein the top portion of the hard mask has a first thickness, and the sidewall portions of the hard mask have second thicknesses smaller than the first thickness.

7. The method of claim 1 further comprising:
forming a plurality of sacrificial layers, wherein the plurality of semiconductor nanostructures and the plurality of sacrificial layers are located alternatingly;
removing the plurality of sacrificial layers, wherein the hard mask is formed after the plurality of sacrificial layers are removed; and
after the second oxide layers are formed, forming a gate stack, wherein the gate stack comprises portions between the plurality of semiconductor nanostructures.

8. The method of claim 1, wherein when the first oxidation process is performed, the inner portions of the hard mask comprise at least inner parts remaining.

9. The method of claim 1, wherein after the etching the sidewall portions of the hard mask, the sidewalls of the plurality of semiconductor nanostructures are exposed.

10. The method of claim 9, wherein after the etching the sidewall portions of the hard mask, the inner portions of hard mask are laterally recessed more than respective ones of the sidewalls of the plurality of semiconductor nanostructures.

11. A method comprising:
forming a plurality of semiconductor nanostructures and a plurality of sacrificial layers, wherein the plurality of semiconductor nanostructures and the plurality of sacrificial layers are located alternatingly;
removing the plurality of sacrificial layers to leave spaces between the plurality of semiconductor nanostructures;
oxidizing outer portions of the plurality of semiconductor nanostructures to form oxide layers that encircle inner portions of the plurality of semiconductor nanostructures, wherein each of the oxide layers comprises:
sidewall portions on sidewalls of the inner portions of the plurality of semiconductor nanostructures, wherein the sidewall portions have a first thickness; and
top portions on tops of the inner portions of the plurality of semiconductor nanostructures, wherein the top portions have a second thickness smaller than the first thickness; and
forming a gate stack in the spaces between the plurality of semiconductor nanostructures.

12. The method of claim 11, wherein the sidewall portions of the oxide layers are formed through more oxidation processes than the top portions.

13. The method of claim 11, wherein the oxide layers further comprise bottom portions at bottoms of the inner portions of the plurality of semiconductor nanostructures, and wherein the bottom portions have the second thickness.

14. The method of claim 11, wherein the oxidizing the outer portions of the plurality of semiconductor nanostructures comprises:
performing a first oxidation process to oxidize sidewall parts of the plurality of semiconductor nanostructures, wherein top parts and bottom parts of the plurality of semiconductor nanostructures are protected from the first oxidation process.

15. The method of claim 14, wherein the top parts and the bottom parts of the plurality of semiconductor nanostructures are protected by a hard mask that fills the spaces between the plurality of semiconductor nanostructures, and the method further comprises:
performing a second oxidation process to oxidize the top parts of the plurality of semiconductor nanostructures to form the top portions of the oxide layers.

16. The method of claim 15 further comprising, before the first oxidation process:
forming the hard mask on the plurality of semiconductor nanostructures; and
partially etching the hard mask.

17. The method of claim 16 further comprising, before the partially etching the hard mask, performing a treatment process to treat a top part of the hard mask, and a lower part of the hard mask is protected from being treated by the top portion, wherein in the partially etching the hard mask, the lower part of the hard mask is removed.

18. A method comprising:
forming a plurality of semiconductor nanostructures, wherein upper ones of the plurality of semiconductor nanostructures overlap lower ones of the plurality of semiconductor nanostructures;
forming source and drain regions joining to opposing ends of the plurality of semiconductor nanostructures;
forming an oxide layer encircling a nanostructure of the plurality of semiconductor nanostructures, wherein the oxide layer comprises:
a sidewall portion on a sidewall of the nanostructure, wherein the sidewall portion has a first thickness; and
a top portion overlying the nanostructure; and
a bottom portion overlying the nanostructure, wherein the top portion and the bottom portion have second thicknesses smaller than the first thickness; and
forming a gate stack, wherein the gate stack comprises parts in spacings between the plurality of semiconductor nanostructures.

19. The method of claim 18, wherein ratios of the first thickness to the second thicknesses are greater than about 1.2.

20. The method of claim 19, wherein the ratios are greater than about 2.
